(19) United States
(12) Patent Application Publication
(10) Pub. No.: US 2016/0342082 A1
(43) Pub. Date: Nov. 24, 2016

(54) ULTRAVIOLET MASK AND METHOD OF MANUFACTURING THE SAME

(71) Applicant: SHENZHEN CHINA STAR OPTEOELECTRONICS TECHNOLOGY CO LTD., Shenzhen, Guangdong (CN)

(72) Inventor: Yanfeng FU, Shenzhen, Guangdong (CN)

(21) Appl. No.: 14/367,184

(22) PCT Filed: May 23, 2014
(86) PCT No.: PCT/CN2014/078297

§ 371 Date: Jun. 19, 2014

(30) Foreign Application Priority Data
May 21, 2014 (CN) 201410217015.3

(51) Int. Cl. G03F 7/00; G03F 7/32; G03F 7/40; G03F 7/20

(52) U.S. Cl. CPC G03F 7/0007; G03F 7/20; G03F 7/32; G03F 7/40

(57) ABSTRACT

An ultraviolet mask and a method of manufacturing the same. The ultraviolet mask includes a black matrix photoresist layer covering the display region of the color filter substrate; the manufacturing method includes: covering black matrix photoresist material on the color filter substrate, selectively removing the black matrix photoresist material distributed on the non-display region of said substrate, while maintaining the black matrix photoresist material distributed on the display region of the substrate, and solidifying the black matrix photoresist material distributed on the display region so as to form the ultraviolet mask. The CF process to replaces the existing Array process, which may implement the manufacturing of ultraviolet mask only through the color filter black matrix (CF BM) yellow light process, thus skipping one filming, one etching and one stripping process compared with the Array process, hence achieving indirect manufacturing and reducing the manufacturing time as well as the cost.

### TECHNICAL FIELD

The present invention relates to the display technical field, and specifically relates to a method of preparing a ultraviolet mask (UV MASK) and the ultraviolet mask

### BACKGROUND

Currently, in the cell process of the TFT LCD (Thin Film Transistor-Liquid Crystal Display), after fitting the Array glass to the CF (Color Filter) glass, in order to avoid negative effect such as leakage of liquid crystal in the LCD cell, reaction between liquid crystal and frame seal and the penetration of external contaminant, the frame seal should be solidified immediately. Referring to FIG. 1, wherein: 100: ultraviolet mask substrate; 101, 102, 103, 104: cross mark for aligning the frame seal solidifying device; 110: a number of diamond patterns for blocking the UV light of the display region on the ultraviolet mask substrate; during the solidifying of the frame seal, the UV mask substrate should be used to block the display region, and frame seal outside the display region is exposed; when solidifying the frame seal, the liquid crystal in the display region of the liquid crystal cell should be prevented from being irradiated by UV light.

Currently, the manufacturing of UV Mask is generally completed on the Array glass, which may include the filming, yellow light, etching, stripping, the protective film forming processes, and so on, and the essentials of the respective process are as follows:

Filming: Normally the conventional light-proof metal layer is adopted, since the metal has low penetration rate and may block the ultraviolet light.

Yellow light: currently there are two exposure methods, wherein:

method one is purchasing the UV Mask for exposure;

method two is performing exposure in two steps, wherein the first step is using the gate shading mask plate to expose the aligning mark for aligning the frame seal solidifying device, wherein, the aligning mask is generally designed on the gate mask plate; the second step is using the block plate of the exposure device to block the display region so as not to be exposed, exposing the non-display region other than the exposed region in the first step, and after development, the display region and the cross mark positions have photoresist protection, while the photoresist may react with the developer on the other non-display region.

The above scenario is the Array yellow light generally using the active photoresist, while in the case of the negative photoresist, the second step may be exposing the display region while blocking the non-display region so as not to be exposed.

Wherein, method one is quick and simple compared with method two, but will cost a shading mask plate; method two uses the block plate of the exposure device to perform exposure, although it may save the UV mask shading mask plate, the resulting exposure method will be complex and less efficient (for the reference, please refer to CN101986206A). Currently, under the situation where the precision of the exposure device blocking plate may reach the precision of the UV Mask, normally, the method two will be used to save the cost.

Etching: etching the metal layer of the non-display region, while reserving the metal of display region.

Photoresist stripping: manufacturing the aligning cross mark of the frame seal solidifying device and the UV Mask blocking the metal of the display region.

Filming of the protective film: filming on the surface of the metal layer so as to protect the metal layer from being eroded, and the non-metal film such as silicon nitride and silicon dioxide and so on can be used.

Specifically, referring to FIGS. 2-3, the manufacturing of the UV Mask in the prior art mainly includes the following steps:

S210: metal filming, that is, using the metal film 202 (such as chromium film) to cover the Array glass substrate 201, and blocking the ultraviolet light using the low penetration rate of the metal film;

S220: Array yellow light coating photoresist, that is, coating Array yellow light photoresist 203 on the metal film 202;

S230: Array yellow light exposure, that is, using the Array exposure device blocking plate 204 to block the Array yellow light photoresist 203 distributed in the display region, and exposing the Array yellow light photoresist in the non-display region;

S240: Array yellow light development, that is, using the developer to remove the Array yellow light photoresist in the non-display region, while reserving the Array yellow light photoresist 205 distributed in the display region;

S250: Array yellow light roasting, that is, roasting the Array yellow light photoresist 203 reserved in the display region so as to solidify the same;

S260: etching the metal film in the region not protected by the Array yellow light photoresist;

S270: stripping the Array yellow light photoresist remained on the surface of the metal film;

S280: forming protective film 206 on the remaining surface of the metal film.

Obviously, the manufacturing method of the ultraviolet mask in the prior art is rather complex, and the cost thereof is also relatively high.

In conclusion, the method of forming UV mask plate by using the ARRAY process as mentioned above is complex in techniques and operation, thus prolonging the working time and increasing the cost.

### SUMMARY

With respect to the defect in the prior art, the present invention aims to provide a method of manufacturing UV mask and the UV mask, which can simplify the manufacturing flow and shortening the production cycle.

To achieve the above purpose, the present application adopts the following technical solutions:

a method of manufacturing UV mask, including: covering light screening material on the color filter substrate, selectively removing the light screening material distributed on the non-display region of said substrate, while maintaining the light screening material distributed on the display region of the substrate, so as to form the ultraviolet mask in the display region.

As one of the specific embodiments, the method of manufacturing UV mask may include:

covering black matrix photoresist material on the color filter substrate, selectively removing the black matrix photoresist material distributed on the non-display region of said substrate, while maintaining the black matrix photoresist material distributed on the display region of the substrate, and

solidifying the black matrix photoresist material distributed on said display region so as to form the ultraviolet mask.

As one of the preferred embodiments, the method of manufacturing UV mask may include:

(1) covering a black matrix photoresist materical on the color filter substrate;

(2) selectively exposing one of the black matrix photoresist material distributed on the non-display region and the black matrix photoresist material distributed on the display region, while not exposing the rest one;

(3) removing the black matrix photoresist material distributed on the non-display region while maintaining the black matrix photoresist material distributed on the display region;

(4) solidifying the black matrix photoresist material distributed on said display region so as to form the ultraviolet mask.

Furthermore, said step (2) may include:

using a black matrix shading mask plate to expose the aligning mark for aligning the frame seal solidifying device, and

using a plate of the color filter exposure device to block said non-display region, so as not to expose the black matrix photoresist material distributed on the non-display region while exposing the black matrix photoresist material distributed on the display region.

Furthermore, said step (3) may include:

removing the black matrix photoresist material distributed on the non-display region using the developer.

Furthermore, said step (4) may include: using at least the roasting method to process the black matrix photoresist material distributed on said display region so as to solidify the same.

As one of the preferred embodiments, the method of manufacturing UV mask may further include: forming protective layer at least on the solidified black matrix photoresist material after solidifying the black matrix photoresist material distributed on the display region.

An ultraviolet mask includes a black matrix photoresist layer covering the display region of the color filter substrate.

As one of the preferred embodiments, a protective layer is further coated on said black matrix photoresist layer.

Preferably, said black matrix photoresist material includes but not is not limited to the black resin material modified due to the light radiation having selected wavelength.

Furthermore, the material constituting said protective layer may select but is not limited to silicon nitride, silicon dioxide or ITO, etc., preferably the ITO.

Compared with the prior art, the advantages of the present invention include: the present invention adopts the CF process to replace the existing Array process, which may implement the manufacturing of ultraviolet mask only through the color filter black matrix (CF BM) yellow light process, thus skipping one filming, one etching and one stripping process compared with the Array process, hence reducing manufacturing steps and reducing the manufacturing time as well as the cost.

### BRIEF DESCRIPTION OF THE DRAWINGS

FIG. 1 is a structural diagram of the prior UV mask.

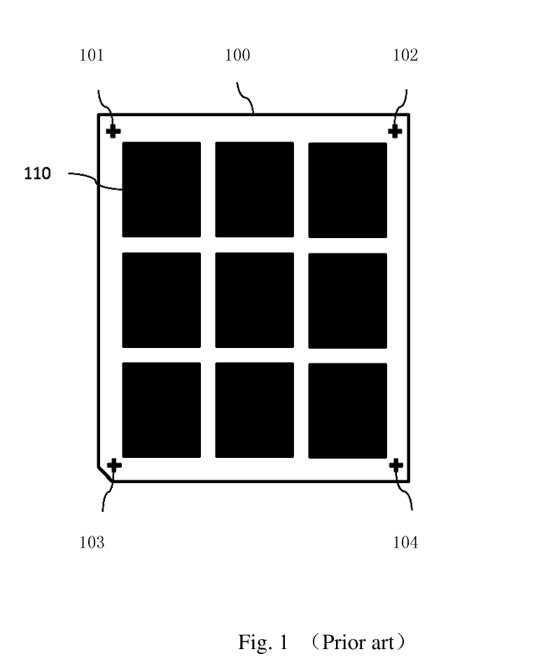

FIG. 2 is a process flow chart of manufacturing UV mask using the prior Array process.

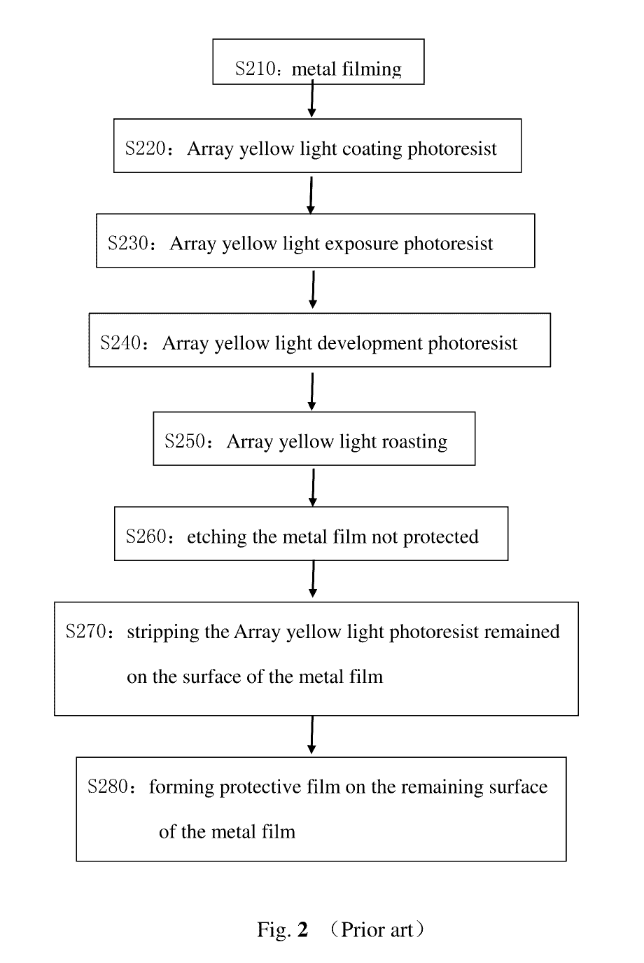

FIG. 3 is another process flow chart of manufacturing UV mask using the prior Array process.

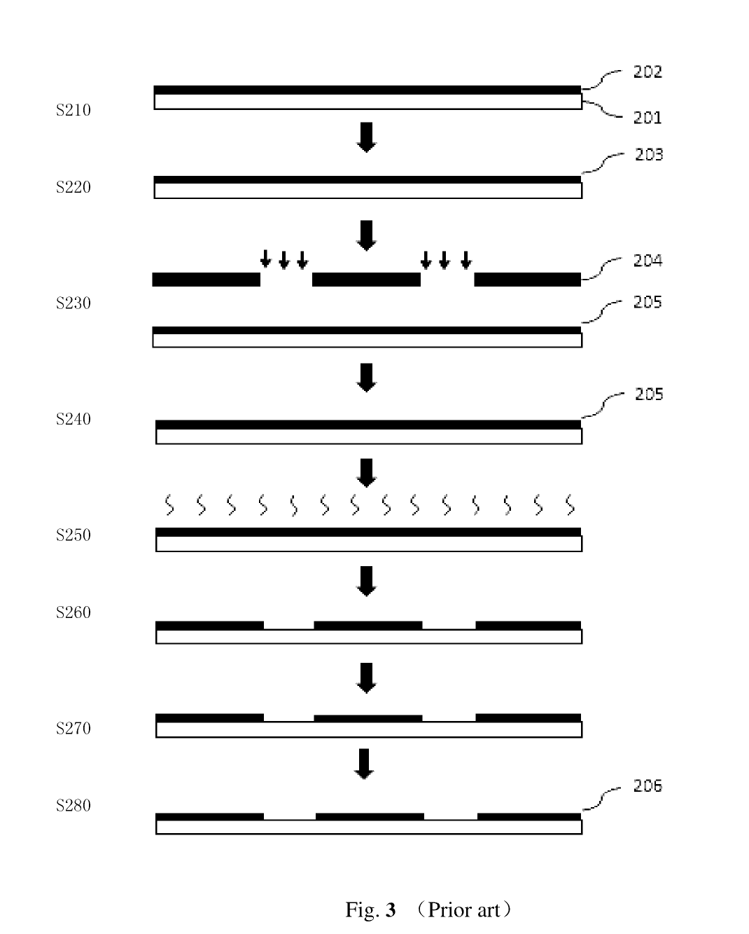

FIG. 4 is a process flow chart of manufacturing UV mask using CF BM as recorded in one of the specific embodiment in the present invention.

FIG. 5 is another process flow chart of manufacturing UV mask using CF BM as recorded in one of the specific embodiment in the present invention.

### DETAILED DESCRIPTION OF EXEMPLARY EMBODIMENTS

In view of the various defects existing in the prior art, the inventor of the present invention raises the technical solution of the present invention after much study and practice, which has almost perfectly solve the defects of the UV mask process in the prior art by means of the method never expected by those skilled in the art.

The technical concept and principle of the present invention will be further illustrated hereafter.

One aspect of the present invention provides a method of manufacturing UV mask, mainly including: covering light screening material on the color filter (CF) substrate, selectively removing the light screening material distributed on the non-display region of said substrate, while maintaining the light screening material distributed on the display region of the substrate, so as to form the ultraviolet mask in the display region.

In the present invention, the aforementioned light screening material may adopt various materials having high light screening performance which are well-known in industry according to the actual needs, preferably the black matrix photoresist material, and particularly the black resin material modified due to the light radiation having selected wavelength, such as the photosensitive resin scattered with light screening paint, which is advantageous in its low cost and usability, and may not cause environment pollution during the usage.

In the present invention, the suitable black resin material may include the resin used for binder, which may include the carboxyl, the compound including ethylenically unsaturated bond, the photopolymerization initiator, the thiol compound and the organic solvent, etc. Wherein the scattered light screening paint may be the carbon black and so on. Also, said black resin material can be acquired from market or prepared by using the method recorded in the prior publication (for example, the Korean patent application No. 1995-0702313 and JP-A-2000-227654, etc.), thus the details thereof will no longer be described.

It can be easily understood that, the aforementioned “light having selected wavelength” is corresponding to the inherent property of the black resin material, which can be the UV light and visible light (such as yellow light) and so on, while the duration of the radiation also depends on the solidifying speed of the black resin material.

Furthermore, in a preferred embodiment of the present invention, the method of manufacturing the UV mask may include:

covering black matrix photoresist material on the color filter substrate, selectively removing the black matrix photoresist material distributed on the non-display region of said substrate, while maintaining the black matrix photoresist material distributed on the display region of the substrate, and

solidifying the black matrix photoresist material distributed on said display region so as to form the ultraviolet mask.

Due to the low penetration rate of the aforementioned black matrix photoresist material of the color filter substrate, said material may perform the function of blocking the light and preventing the light leakage when blocking the region not requiring light transmission between the TFT and the pixel, also, the roasted black matrix photoresist material may produce the same effect as the metal film blocking UV light.

Furthermore, the method of manufacturing UV mask may include:

(1) covering the black matrix photoresist layer on the color filter substrate;

(2) selectively exposing one of the black matrix photoresist material distributed on the non-display region and the black matrix photoresist material distributed on the display region, while not exposing the rest one;

(3) removing the black matrix photoresist material distributed on the non-display region while maintaining the black matrix photoresist material distributed on the display region;

(4) solidifying the black matrix photoresist material distributed on said display region so as to form the ultraviolet mask.

In the aforementioned step (1) of the present invention, based on the properties of the black matrix photoresist material, the black matrix photoresist material can be applied to the color filter substrate through physical or chemical deposition, spinning, spraying, printing and so on, especially coating and printing and the like, so as to form the black matrix photoresist material having required thickness, thus achieving blocking of light.

When adopting the black resin material as the black matrix photoresist material, considering that the black resin material may be the positive photoresist material or the negative photoresist material, thus in the aforementioned step (2), the black matrix photoresist material distributed on the non-display region or the black matrix photoresist material distributed on the display region are selectively exposed and then modified.

For example, as one of the optional specific embodiments, when using the negative black resin material, said step (2) may include:

using the black matrix shading mask plate to expose the aligning mark for aligning the frame seal solidifying device, and

using the plate of the color filter exposure device to block said non-display region, so as not to expose the black matrix photoresist material distributed on the non-display region while exposing the black matrix photoresist material distributed on the display region.

On the contrary, if the positive black resin material is used, the black matrix photoresist material distributed on the display region should not be exposed.

Accordingly, said step (3) may include: removing the black matrix photoresist material distributed on the non-display region or the black matrix photoresist material distributed on the display region by using the developer.

The developer mentioned here can be easily selected from the various developers well-known in the industry based on the type of the black matrix photoresist material.

Furthermore, said step (4) may include: using the roasting method and so on process the black matrix photoresist material distributed on said display region so as to solidify the same, but not limited thereto.

Also, in order to prevent the black matrix photoresist material distributed on the display region from being damaged, preferably, the protective layer can be formed at least on the solidified black matrix photoresist material after solidifying the black matrix photoresist material distributed on the display region. For example, if the black resin material is used, since it belongs to organic material, when the UV light irradiates on the BM photoresist, the UV light will form ozone in the air on the surface of the BM, while the ozone may erode the resin material, thus a long term irradiation may cause the obscission of the BM photoresist. Thus a protective layer should be further added to protect the BM photoresist.

More preferably, the protective layer of organic and/or inorganic material which is well-known in the industry can be used to cover all the regions of the color filter substrate for setting one side of the UV mask, hence further facilitating the operation.

Furthermore, the material constituting said protective layer may select but is not limited to silicon nitride, silicon dioxide or ITO (tin indium oxide), etc., preferably the ITO, etc.

Another aspect of the present invention provides an ultraviolet mask including the black matrix photoresist layer covering the display region of the color filter substrate.

As one of the preferred embodiments, a protective layer is further coated on said black matrix photoresist layer.

Obviously, the present invention adopts the CF BM process to replace the existing method of manufacturing UV mask using Array process, which may implement the manufacturing of ultraviolet mask only through the yellow light and filming protective film processes, thus reducing one filming, one etching and one stripping process compared with the Array process, hence simplifying the manufacturing process and reducing the manufacturing time as well as the cost.

Below the technical solutions of the present disclosure are further explained in detail in conjunction with the embodiments and the accompanying drawings.

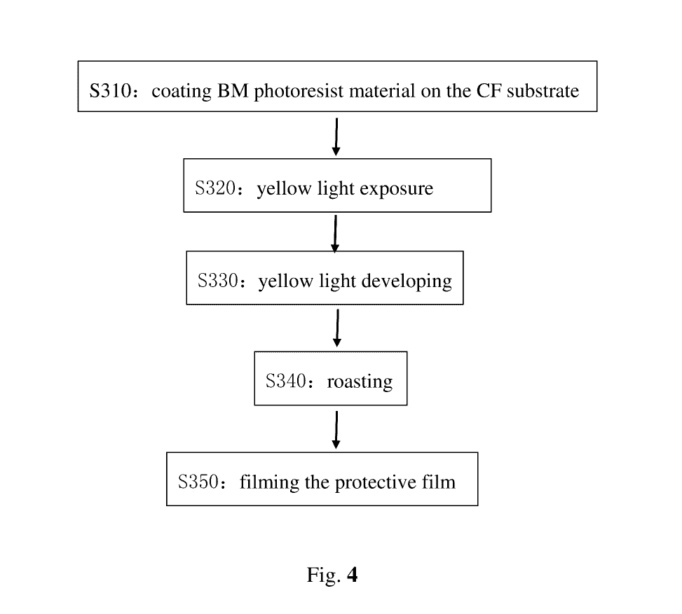

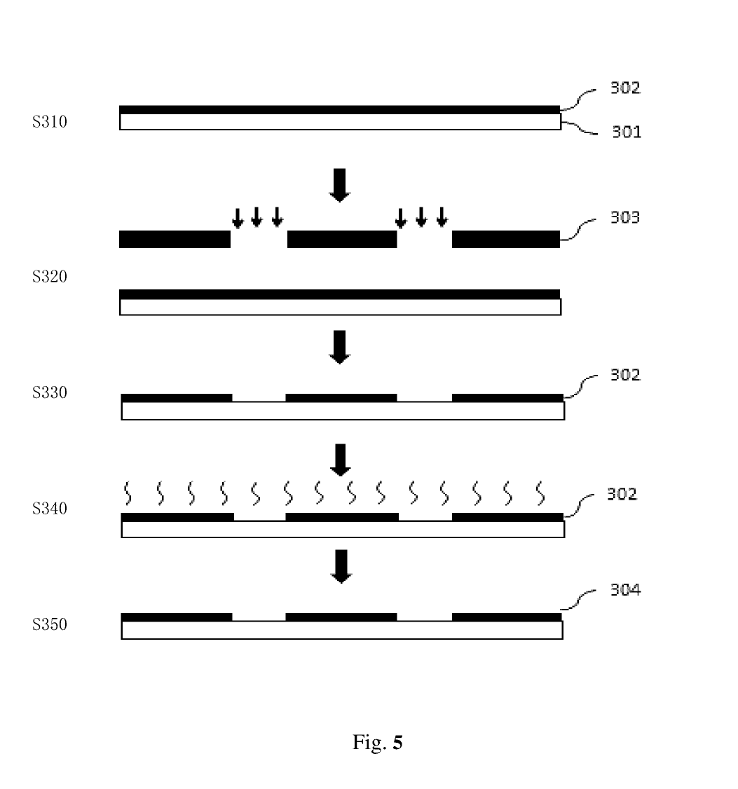

Referring to FIG. 4 and FIG. 5, in a particular embodiment of the present invention, the negative black matrix photoresist material is adopted, and the method of manufacturing UV mask by using said black matrix photoresist material may include the following steps:

S310: coating, coating the black matrix (BM) photoresist material 302 on the color filter (CF) substrate 301;

S320: exposure (yellow light exposure), including: step one, using the black matrix shading mask plate to expose the aligning mark for aligning the frame seal solidifying device; step two, using the plate 303 of the color filter exposure device to block the non-display region so as not to be exposed, while exposing the display region;

S330: developing (yellow light developing), removing the black matrix photoresist material of the non-display region not be exposed by using the developer reaction, while maintaining the black matrix photoresist material of the display region which has been exposed;

S340: roasting: roasting the black matrix photoresist material maintained on the display region so as to solidify the same;

S350: filming the protective film 304, using the ITO in the CF process to coat the film, so as to protect the black matrix photoresist layer of the display region.

Also, it should be noted that, the precision of the UV mask is mainly determined by the precision of the exposure device plate, normally, the precision of the CF exposure device plate and the precision of the Array exposure device plate are identical to each other. Therefore, the precision of the UV mask of the present invention may be at least identical to the current method.

It should be understood that, the above embodiment is only used to illustrate the technical concept and feature of the present invention, and the purpose thereof is familiarize the person skilled in the art to understand the content of the present invention and carry it out, which cannot restrict the protection scope of the present invention based on above. Any equivalent transformation or modification made in the spirit of the present invention should all be included within the protection scope of the present invention.

1. A method of manufacturing UV mask, wherein covering light screening material on the color filter substrate, removing the light screening material distributed on the non-display region of the color filter substrate, while maintaining the light screening material distributed on the display region of the color filter substrate, so as to form the ultraviolet mask in the display region.

2. The method of claim 1, wherein covering black matrix photoresist material on the color filter substrate, removing the black matrix photoresist material distributed on the non-display region of the color filter substrate, while maintaining the black matrix photoresist material distributed on the display region of the color filter substrate, and
solidifying the black matrix photoresist material distributed on said display region so as to form the ultraviolet mask.

3. The method of claim 2, further comprising the following steps:
(1) covering black matrix photoresist material on the color filter substrate;
(2) selectively exposing one of the black matrix photoresist material distributed on the non-display region and the black matrix photoresist material distributed on the display region, while not exposing the rest one;
(3) removing the black matrix photoresist material distributed on the non-display region while maintaining the black matrix photoresist material distributed on the display region;
(4) solidifying the black matrix photoresist material distributed on said display region so as to form the ultraviolet mask.

4. The method of claim 3, characterized in that: step (2) including:
using the black matrix shading mask plate to expose the aligning mark for aligning the frame seal solidifying device, and
using a plate of the color filter exposure device to block said non-display region, so as not to expose the black matrix photoresist material distributed on the non-display region while exposing the black matrix photoresist material distributed on the display region.

5. The method of claim 4, characterized in that: step (3) including:
removing the black matrix photoresist material distributed on the non-display region using the developer.

6. The method of claim 2, step (4) including: using at least the roasting method to process the black matrix photoresist material distributed on said display region so as to solidify the same, said black matrix photoresist material includes the black resin material modified due to the light radiation having selected wavelength.

7. The method of claim 3, step (4) including: using at least the roasting method to process the black matrix photoresist material distributed on said display region so as to solidify the same, said black matrix photoresist material includes the black resin material modified due to the light radiation having selected wavelength.

8. The method of claim 4, step (4) including: using at least the roasting method to process the black matrix photoresist material distributed on said display region so as to solidify the same, said black matrix photoresist material includes the black resin material modified due to the light radiation having selected wavelength.

9. The method of claim 5, step (4) including: using at least the roasting method to process the black matrix photoresist material distributed on said display region so as to solidify the same, said black matrix photoresist material includes the black resin material modified due to the light radiation having selected wavelength.

10. The method of claim 1, wherein the method further including: forming protective layer at least on the solidified black matrix photoresist material after solidifying the black matrix photoresist material distributed on the display region, wherein the material constituting said protective layer includes silicon nitride, silicon dioxide or ITO.

11. The method of claim 2, wherein the method further including: forming protective layer at least on the solidified black matrix photoresist material after solidifying the black matrix photoresist material distributed on the display region, wherein the material constituting said protective layer includes silicon nitride, silicon dioxide or ITO.

12. The method of claim 3, wherein the method further including: forming protective layer at least on the solidified black matrix photoresist material after solidifying the black matrix photoresist material distributed on the display region, wherein the material constituting said protective layer includes silicon nitride, silicon dioxide or ITO.

13. The method of claim 4, wherein the method further including: forming protective layer at least on the solidified black matrix photoresist material after solidifying the black matrix photoresist material distributed on the display region, wherein the material constituting said protective layer includes silicon nitride, silicon dioxide or ITO.

14. The method of claim 5, wherein the method further including: forming protective layer at least on the solidified black matrix photoresist material after solidifying the black matrix photoresist material distributed on the display region, wherein the material constituting said protective layer includes silicon nitride, silicon dioxide or ITO.

15. An ultraviolet mask, wherein including a black matrix photoresist layer coated on the display region of the color filter substrate.

16. The ultraviolet mask of claim 15, wherein the material constituting said black matrix photoresist layer includes the black resin material modified due to the light radiation.

17. The ultraviolet mask of claim 16, wherein a protective layer is coated at least on the black matrix photoresist layer.

18. The ultraviolet mask of claim 17, wherein the material constituting said protective layer includes silicon nitride, silicon dioxide or ITO.
